(19) United States
(12) Patent Application Publication
(10) Pub. No.: US 2014/0291569 A1
(43) Pub. Date: Oct. 2, 2014

(54) NANOROD AND METHOD OF MANUFACTURING THE SAME

(71) Applicant: Intellectual Discovery Co., Ltd., Seoul (KR)

(72) Inventors: Hyeong tag JEON, Seoul (KR); Hagyoung CHOI, Seoul (KR); Seokyoon SHIN, Goyang-si (KR); Giyul HAM, Seoul (KR)

(73) Assignee: Intellectual Discovery Co., Ltd., Seoul (KR)

(21) Appl. No.: 13/891,998

(22) Filed: May 10, 2013

(30) Foreign Application Priority Data
Mar. 28, 2013 (KR) 10-2013-0033852

(51) Int. Cl. H01L 41/37; H01L 41/18

(52) U.S. Cl. CPC H01L 41/37; H01L 41/183
USPC 252/62.9 R; 427/100

(57) ABSTRACT

A nanorod and a method of manufacturing the same are disclosed, and a nanorod including a ZnO nanorod; and a coating layer disposed on a ZnO surface and including RuO₂ nanoparticles are disclosed concretely.

### CROSS-REFERENCE TO RELATED APPLICATION

This application claims priority to and the benefit of Korean Patent Application No. 10-2013-0033852 filed in the Korean Intellectual Property Office on Mar. 28, 2013, the entire contents of which are incorporated herein by reference. In addition, the entire contents of “Journal of Materials Chemistry Cite this: J. Mater. Chem., 2012, 22, 14141” are incorporated herein by reference.

### BACKGROUND OF THE INVENTION

(a) Field of the Invention

A nanorod and a method of manufacturing the same are disclosed.

(b) Description of the Related Art

A 1-dimensional nanomaterial such as a nanorod and a nanowire means a material having a diameter from several nanometers (nm) to several tens of nanometers (nm) and a length from several hundreds of nanometers (nm) to several micrometers (μm), and the 1-dimensional nanomaterial exhibits various physical and chemical properties that cannot be exhibited in a bulk material in the related art.

Accordingly, a nanorod, a nanowire, a nanostructure, and the like using zinc oxide exhibit excellent light transmittance, a large piezoelectric index, and a UV emission property, and thus is applied as a basic material for implementing a nano-sized electronic device, optical device, or sensor in various kinds of devices such as a transparent electrode, an optical cell device, an optical wave guide, and a gas sensor of a UV light-emitting diode (LED) or a laser diode (LD).

As described above, the nanorod, the nanowire, the nanostructure, and the like play an important role as an essential material, and thus development of a synthesis method of the high-quality 1-dimensional nanorod, nanowire, nanostructure, and the like is the focus of attention.

However, the nanostructure using zinc oxide manufactured until now does not sufficiently satisfy properties required in electric devices.

Therefore, there is a demand for development of a novel nanostructure having improved electric and chemical properties.

The above information disclosed in this Background section is only for enhancement of understanding of the background of the invention, and, therefore, it may contain information that does not form the prior art that is already known in this country to a person of ordinary skill in the art.

### SUMMARY OF THE INVENTION

A novel nanostructure having improved electric and chemical properties is provided.

An exemplary embodiment provides a nanorod including: a ZnO nanorod; and a coating layer disposed on a ZnO surface and including RuO₂ nanoparticles.

The RuO₂ nanoparticles may have an average particle diameter of 20 nm or less. More specifically, the average particle diameter may be 10 to 20 nm.

The ZnO nanorod may have a diameter of 20 nm or less.

The ZnO nanorod may have a length of 300 nm or less.

The coating layer disposed on the ZnO surface and including the RuO₂ nanoparticles may be an island type or a layered type.

Another exemplary embodiment provides a method of manufacturing a nanorod, including: forming a ZnO nanorod on a substrate; and forming a coating layer including RuO₂ nanoparticles on a surface of the ZnO nanorod formed on the substrate.

The forming of the coating layer including the RuO₂ nanoparticles on the surface of the ZnO nanorod formed on the substrate may be performed by an atomic layer deposition method.

The atomic layer deposition method may be performed in at least one or more cycles.

The atomic layer deposition method may be performed in one or more cycles and less than 70 cycles.

The atomic layer deposition method may be performed 30 or more and 50 or less cycles.

The forming of the ZnO nanorod on the substrate may be performed by a hydrothermal synthesis method.

The substrate may be a silicon substrate, a plastic substrate, a glass substrate, a metal substrate, quartz, a metal oxide substrate, a metal nitride substrate, or a combination thereof.

The forming of the ZnO nanorod on the substrate may include forming a ZnO seed layer including a zinc precursor and HMT (hexamethylenetetramine) on the substrate; and heating the substrate on which the ZnO seed layer is formed in a hydrothermal synthesis reactor to form the ZnO nanorod.

In the forming of the ZnO seed layer including the zinc precursor and HMT (hexamethylenetetramine) on the substrate, the zinc precursor may be zinc nitrate, zinc sulfate, zinc chloride, zinc acetate, hydrate thereof, or a combination thereof.

The heating of the substrate on which the ZnO seed layer is formed in the hydrothermal synthesis reactor to form the ZnO nanorod may be a step of forming the ZnO nanorod under a condition of a temperature of 70 to 400° C. and a time of 30 minutes to 2 hours.

The forming of the coating layer including the RuO₂ nanoparticles on the surface of the ZnO nanorod formed on the substrate may be performed by the atomic layer deposition method, and the atomic layer deposition method may be performed by using a ruthenium precursor, and argon-oxygen mixed gas as raw materials under a condition of a temperature of 100 to 400° C.

The ruthenium precursor may be bis(ethylcyclopentadienyl)ruthenium (Ru(EtCp)₂).

Yet another exemplary embodiment provides a nanorod manufactured according to the aforementioned exemplary embodiment of the present invention.

Still another exemplary embodiment provides a device including the nanorod according to the aforementioned exemplary embodiment of the present invention.

According to the exemplary embodiments, it is possible to provide a novel nanostructure (e.g., nanorod) having improved electric and chemical properties. More specifically, it is possible to provide a photoelectrochemical cell, a fuel cell, a solar cell, and the like having an improved photoelectric property according to an increase in surface plasmon resonance phenomenon.

### BRIEF DESCRIPTION OF THE DRAWINGS

FIG. 1 is a TEM image of a ZnO nanorod coated with RuO₂ manufactured in the Examples.

FIGS. 2A and 2B are a TEM image and XRD measurement data of the ZnO nanorod coated with RuO₂ manufactured in the Example according to the number of atomic layer deposition method cycles.

FIGS. 3A and 3B are Ru 3d XPS data and VB (valence band) edge spectra data of the ZnO nanorod coated with RuO₂ manufactured in the Example according to the number of the atomic layer deposition method cycles.

FIGS. 4A to 4D are UV-Vis light absorption data and PL data of the ZnO nanorod coated with RuO₂ manufactured in the Example according to the number of the atomic layer deposition method cycles.

FIGS. 5A and 5B are a schematic theoretical explaining view of LSPR coupling for explanation an increase in absorption of visible rays and in UV light emission.

FIG. 6 is analysis data of factors of light absorption and light emission according to the number of the atomic layer deposition methods of the Examples.

### DETAILED DESCRIPTION OF THE EMBODIMENTS

Hereinafter, an exemplary embodiment of the present invention will be described in detail. However, the exemplary embodiment is illustrative only but is not to be construed to limit the present invention, and the present invention is just defined by the scope of the claims as described below.

The present specification includes all the contents of J. Mater. Chem., 2012, 22, 14141 (http://pubs.rsc.orgldoi:10.1039/C2JM31513K) that is the basis of the present invention.

An exemplary embodiment provides a nanorod including: a ZnO nanorod; and a coating layer disposed on a ZnO surface and including RuO₂ nanoparticles.

A surface plasmon phenomenon may be maximized due to the presence of the RuO₂ nanoparticles in the ZnO nanorod. That is, visible absorption and UV light emission may be increased due to an increase in LSPR. The LSPR is an abbreviation of “local surface plasmon resonance”.

More specifically, the RuO₂ nanoparticles may have an average particle diameter of 20 nm or less. More specifically, the average particle diameter may be 10 to 20 nm. In the case where the aforementioned range is satisfied, an effective surface plasmon phenomenon may occur.

The ZnO nanorod may have a diameter of 20 nm or less, or the ZnO nanorod may have a length of 300 nm or less. Generally, the surface plasmon phenomenon effectively occurs in the nanostructure, but the exemplary embodiment is not limited to the aforementioned range.

A specific example of the coating layer disposed on the ZnO surface and including the RuO₂ nanoparticles may be an island type or a layered type.

Another exemplary embodiment provides a method of manufacturing a nanorod, including: forming a ZnO nanorod on a substrate; and forming a coating layer including RuO₂ nanoparticles on a surface of the ZnO nanorod formed on the substrate.

Specifically, for example, the forming of the coating layer including the RuO₂ nanoparticles on the surface of the ZnO nanorod formed on the substrate may be performed by an atomic layer deposition method.

The atomic layer deposition method may be a method that is suitable for uniform coating of a 3-dimensional structure, and will be more specifically described in the exemplary embodiment as described below.

The atomic layer deposition method may be performed in at least one or more cycles. More specifically, the atomic layer deposition method may be performed in one or more cycles and less than 70 cycles, or 30 or more and 50 or less cycles. This may be adjusted according to a desired plasmon effect.

The forming of the ZnO nanorod on the substrate may be performed by a hydrothermal synthesis method, but is not limited thereto.

The atomic layer deposition (ALD) technology is a technology that has been actively studied according to an actual development of nano-leveled semiconductors having a circuit line width of 100 nm or less. The atomic layer deposition technology is a high technology of forming a thin film by an atomic layer unit, in which since a ultra-thin film having excellent uniformity can be deposited, growth may be performed by a hydrothermal synthesis method and a thin film may be formed on a surface of a nanorod having low surface uniformity by deposition of the atomic layer to increase surface uniformity and crystallinity.

To be more specific, the forming of the ZnO nanorod on the substrate may include forming a ZnO seed layer including a zinc precursor and HMT (hexamethylenetetramine) on the substrate; and heating the substrate on which the ZnO seed layer is formed in a hydrothermal synthesis reactor to form the ZnO nanorod.

Further, in the forming of the ZnO seed layer including the zinc precursor and HMT (hexamethylenetetramine) on the substrate, the zinc precursor may be zinc nitrate, zinc sulfate, zinc chloride, zinc acetate, hydrate thereof, or a combination thereof.

Further, the heating of the substrate on which the ZnO seed layer is formed in the hydrothermal synthesis reactor to form the ZnO nanorod may be a step of forming the ZnO nanorod under a condition of a temperature of 70 to 400° C. and a time of 30 minutes to 2 hours. To be more specific, the temperature may be 100 to 350° C. and/or the time may be 30 minutes to 1 hour.

The aforementioned specific hydrothermal synthesis method is an example of a method for effectively manufacturing the ZnO nanorod, but the present invention is not limited thereto.

To be more specific, the forming of the coating layer including the RuO₂ nanoparticles on the surface of the ZnO nanorod formed on the substrate may be performed by the atomic layer deposition method, and the atomic layer deposition method may be performed by using a ruthenium precursor, and argon-oxygen mixed gas as raw materials under a condition of a temperature of 100 to 400° C. To be more specific, the atomic layer deposition method may be performed at 100 to 350° C., 100 to 200° C., or 100 to 150° C.

To be more specific, the ruthenium precursor may be bis(ethylcyclopentadienyl)ruthenium (Ru(EtCp)₂). However, the precursor is not limited thereto.

Further, the specific atomic layer deposition method will be described as an example in the exemplary embodiment as described below.

The substrate may be a silicon substrate, a plastic substrate, a glass substrate, a metal substrate, quartz, a metal oxide substrate, a metal nitride substrate, or a combination thereof, but is not limited thereto.

Yet another exemplary embodiment of the present invention provides a device including the nanorod manufactured by the aforementioned manufacturing method.

The device may be a semiconductor light-emitting device such as light-emitting diode, a transistor, a light detection device, a sensor device, a photoelectrochemical cell, a fuel cell, a solar cell, or the like.

Hereinafter, Examples and Comparative Examples of the present invention will be described. However, the following Example is only the preferred Example of the present invention, but the present invention is not limited to the following Example.

Example: Manufacturing of the ZnO Nanorod

First, the ZnO seed layer having the thickness of 30 nm is deposited on the SiO₂ wafer having the thickness of 100 nm. In this case, diethyl zinc (Zn(CH₂CH₃)₂, DEZ) and deionized water are used as the zinc precursor and the oxidant, respectively. Further, argon gas is used as the carrier and exhausted gas.

The reaction temperature is 150° C., and the pressure is 0.5 Torr.

After the ZnO seed layer is formed, two precursors of zinc nitrate hexahydrate (ZnNO₃₂.6H₂O, sigma aldrich, 99.0% purity) and hexamethylemetetramine (HMT, sigma aldrich, 99.0% purity) are added in the same molar ratio (0.02M) to the Teflon beaker, and hydrothermal synthesis of the ZnO nanorod on the substrate is performed.

Before the substrate is added to the Teflon beaker and hydrothermal synthesis is performed, the Teflon beaker including the precursor solution is maintained at 90° C. for 1 hour, and thus ZnO nanoparticles floating in the beaker may be reduced. Thereafter, the substrate is transferred into the heated precursor solution, and a hydrothermal reaction is performed at the aforementioned temperature for 2 hours.

After the hydrothermal reaction is finished, the substrate is drawn from the precursor solution and immediately washed by deionized water. Subsequently, the substrate may be dried in the air.

Example: Deposition of RuO₂ Nanoparticles on the ZnO Nanorod

After the ZnO nanorod is formed on the substrate, the atomic layer deposition method in which the RuO₂ nanoparticles are deposited on the ZnO nanorod is performed. In this case, bis(ethylcyclopentadienyl)ruthenium (Ru(EtCp)₂) as the ruthenium precursor and argon-oxygen mixed gas [flow rate; Ar/O=15/15 sccm (sccm denotes standard cubic centimeter per minute)] may be used. In this case, the reaction temperature is 350° C. The atomic layer deposition method may be repeated in several cycles.

The ZnO nanorod manufactured by the hydrothermal synthesis method has the diameter of 20 nm or less and the length of 300 nm or less. The RuO₂ nanoparticles may be uniformly deposited by the atomic layer deposition method.

To be more specific, since the RuO₂ nanoparticles are present as a 3-dimensional island type due to high surface energy, the RuO₂ nanoparticles may be effectively 3-dimensionally uniformly deposited on the 3-dimensional ZnO nanorod.

The obtained ZnO nanorod surface has a typical hexagonal wurtzite structure, and (002) alignment is mainly observed. The (002) alignment may have a structure in which ends of Zn and O have polarity. Since Ru is very familiar with bonds to oxygen, the RuO₂ nanoparticles are chemically bonded to an O-rich portion of the ZnO nanorod.

Experimental Example

Experiment Method

Morphological characterizations are measured using the TEM (transmission electron microscopy, JEM-3010TEM, JEOL) with an accelerating voltage of 300 kV.

Crystal structures are measured by using XRD (X-ray diffraction, DMAX-2500, Rigaku, Cu Ka radiation).

Changes in the chemical bonds of the ZnO nanostructure are measured by using XPS (X-ray photoelectron spectroscopy, ESCA Lab-2220I, VG with a Mg source).

Each binding energy was measured based on C-C bonds (284.5 eV).

Optical properties of the ZnO nanostructure are measured by using PL (photoluminescence) using a 325 nm Hd—Cd laser as the excitation source at 4 K and ultraviolet-visible (UV-Vis) spectroscopy.

Finally, the time-resolved PL spectra is measured by using a streak camera technique at 10 K. The light source is a Ti:sapphire laser (MaiTai, Spectra Physics, 100 fs pulse width, 700 nm wavelength and the repetition rate of 80 MHz).

The beam is frequency doubled to 350 nm by using a b-BaB2O4 (BBO) crystal.

The collected PL is dispersed by a 30 cm spectrograph and detected by a streak scope (C10627, Hamamatsu Photonics K.K.) to obtain PL decay curves.

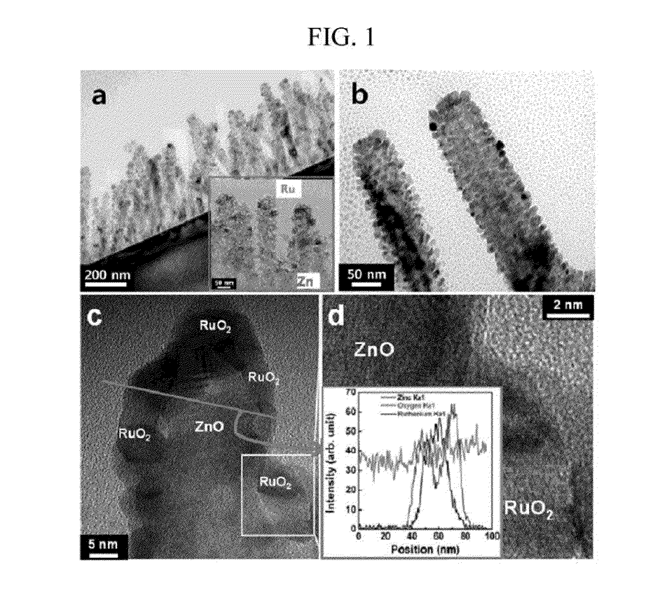

FIG. 1 is a TEM picture of a ZnO nanorod coated with RuO₂ manufactured in the Examples.

To be more specific, FIGS. 1(a) to 1(c) are TEM images of a ZnO nanorod coated with RuO₂ manufactured in the exemplary embodiment according to magnifications. In this case, the RuO₂ nanoparticles were applied on the surface of the ZnO nanorod by 50 atomic layer deposition method cycles.

From FIG. 1, the uniformly applied RuO₂ nanoparticles can be seen.

FIG. 1(d) is a magnified TEM image of a portion of FIG. 1(c).

The drawings in FIGS. 1(a) and 1(d) are TEM-EDS color-mappings and line-scan results of a portion marked in FIG. 1(c), respectively.

The TEM-EDS analysis shows that Zn Kₐ₁, O Kₐ₁ and Ru Kₐ₁ emit X-rays at each position among elements. Further, from the analysis, it can be seen that the average particle diameter of RuO₂ is 20 nm or less.

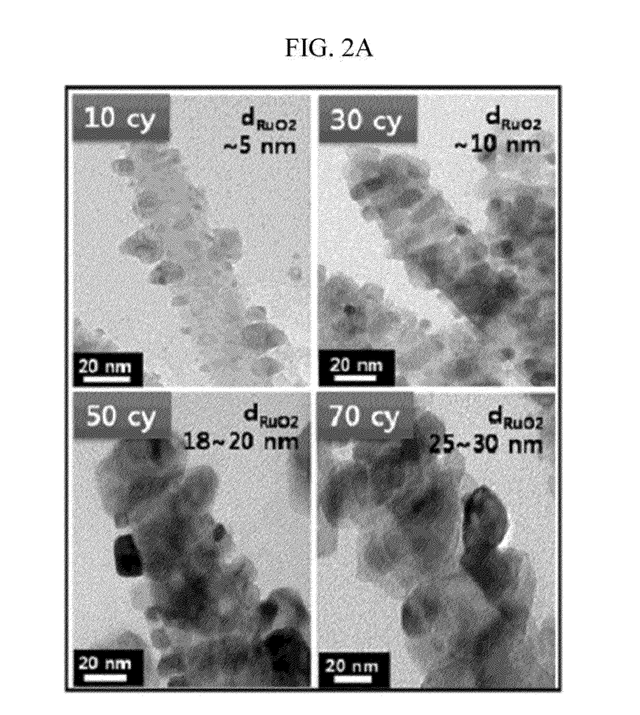

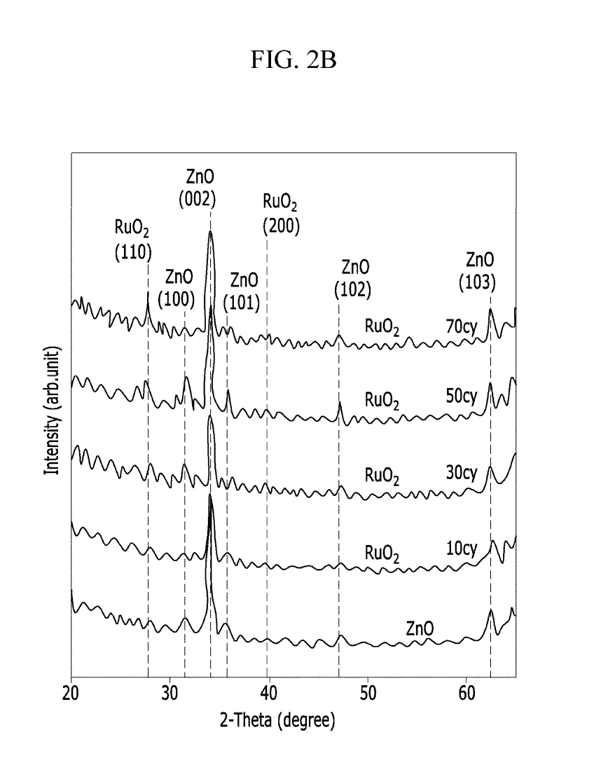

FIGS. 2A and 2B are a TEM image and XRD measurement data of the ZnO nanorod coated with RuO₂ manufactured in the Example according to the number of atomic layer deposition method cycles.

To be more specific, FIG. 2A is TEM images, and FIG. 2B is XRD measurement data.

From the data, the average particle diameter of the RuO₂ nanoparticles was measured to be 5 nm or less or 30 nm or less according to the number of atomic layer deposition method cycles (10 to 70 cycles).

From FIG. 2A, it can be seen that the average particle diameter of the RuO₂ nanoparticles is increased as the number of atomic layer deposition method cycles is increased. Further, it can be seen that the coverage of the ZnO nanorod is increased together with an increase in average particle diameter.

Further, from FIG. 2B, an increase in average particle diameter of the RuO₂ can be seen from the increase of intensity and width of a (110) peak.

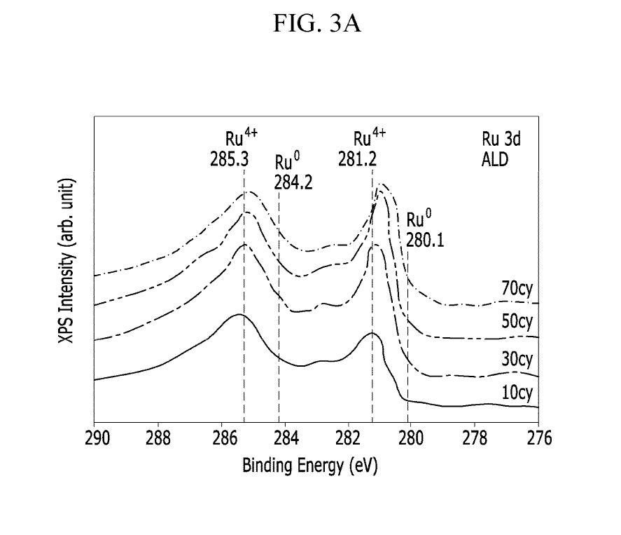

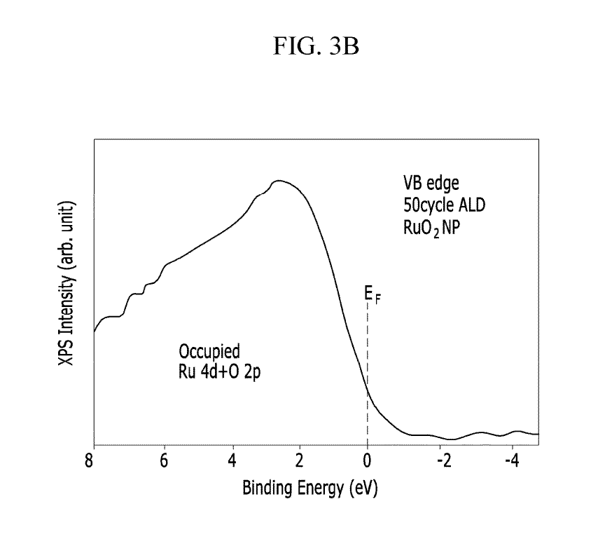

FIGS. 3A and 3B are Ru 3d XPS data and VB (valence band) edge spectra data of the ZnO nanorod coated with RuO₂ manufactured in the Example according to the number of the atomic layer deposition method cycles.

To be more specific, FIG. 3A is Ru 3d XPS data according to the number of atomic layer deposition method cycles. From the data, it can be seen that a main oxidation number of the RuO₂ nanoparticles is Ru⁴⁺.

To be more specific, the Ru 3d XPS binding state has two main spin orbital splitting components, for example, Ru 3d_{5/2} (278-283 eV) and Ru 3d_{3/2} (282-289 eV).

It is known that a metallic Ru⁰ state has 280.1 eV and Ru⁴⁺ (i.e., bulk oxide) of a full oxidation state has 281.2 eV. From the analysis, it can be seen that since the surface of the aforementioned Example has 282.2 eV, the surface has Ru⁴⁺.

Further, FIG. 3B is VB edge XPS spectra data of the Example where 50 atomic nucleus depositions are performed.

Previous studies have shown that RuO₂ has an intrinsic submetallic property and that E_{F} is located in the partially filled Ru 4d state.

As seen in FIG. 3B, the VB maximum value filled in Ru 4d extends to about 0 eV of binding energy, confirming the submetallic property. The submetallic property of RuO₂ may have improved benefits for optical properties, high carrier density and conductivity in comparison to other metal oxides.

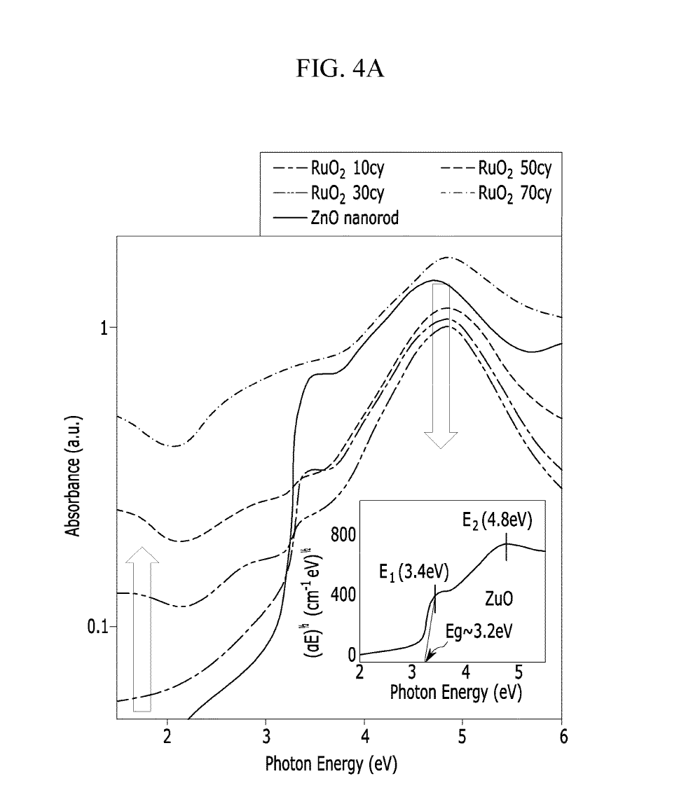

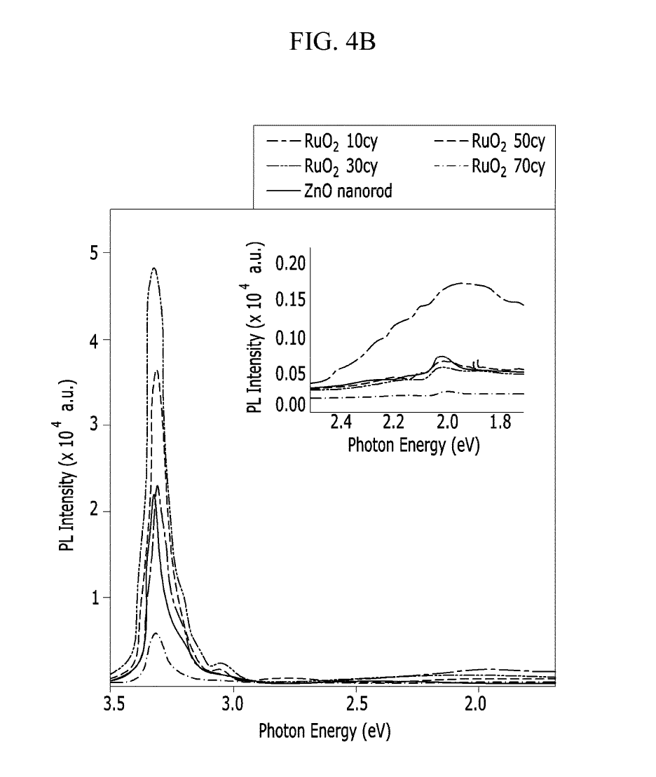

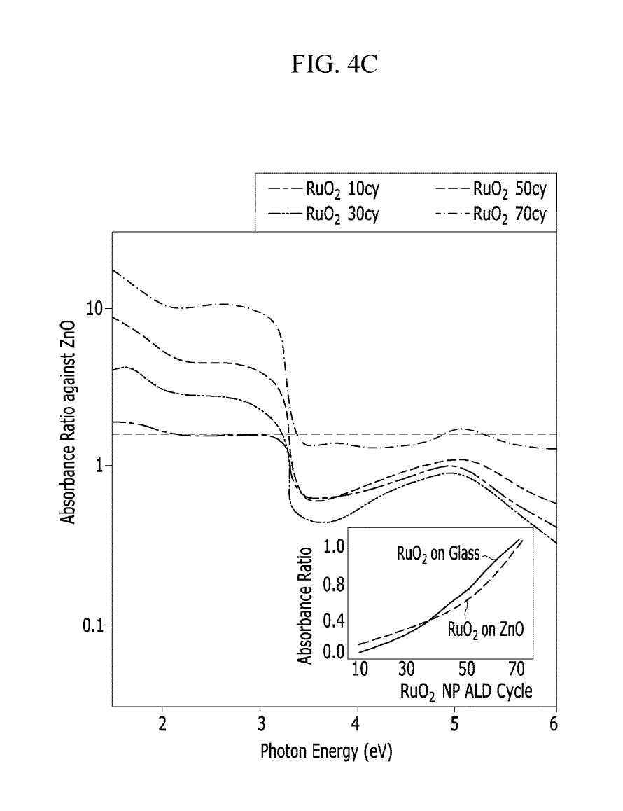

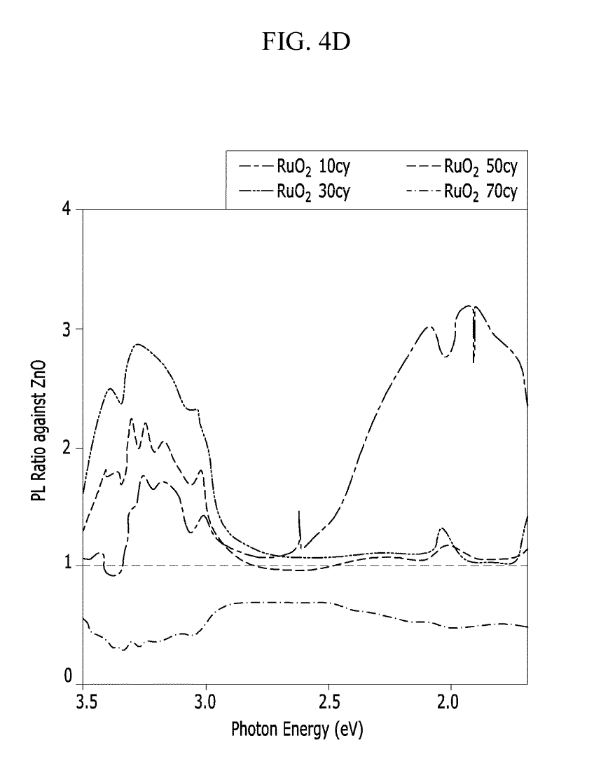

FIGS. 4A to 4D are UV-Vis light absorption data and PL data of the ZnO nanorod coated with RuO₂ manufactured in the Example according to the number of the atomic layer deposition method cycles.

The samples for analyzing FIGS. 4A to 4D were manufactured so that all annealing temperatures were adjusted to 350° C. when the ZnO nanorod was synthesized.

From the raw transmission data before processing from the UV-Vis spectrometer, the optical absorption coefficient (a, cm⁻¹) was extracted for ZnO.

The optical band gap of ZnO was measured to be 3.2±0.05 eV, which is similar to the reported values. However, the overall optical absorption coefficient of the Example was higher than 3.2 eV, which was different from the optical absorption coefficient of bulk ZnO.

This is regarded because the type of ZnO of the Example is the nanorod, and this difference is difficult to be shown in the XRD.

To be more specific, FIG. 4A is logarithmic scale data of UV-Vis absorption spectrum of the ZnO nanorod coated with RuO₂ manufactured in the Example. The graph in FIG. 4A is a Tauc plot ((Ea)^{1/2} vs. photon energy) of the light absorption spectrum, indicating the optical band gap (E_{g,opt}) of ZnO to be 3.2±0.05 eV. From FIG. 4A, it can be seen that visible absorption and UV absorption are asymmetric.

FIG. 4B illustrates PL emission spectra according to the number of atomic layer deposition method cycles of the Example at a low temperature (4 K). It can be seen that most emission lines are shown at 3.33 eV and emission property is improved as compared to the ZnO nanorod (Comparative Example) where RuO₂ is not deposited until the Example where 50 atomic layer deposition method cycles are performed, but is not improved in the Example where 70 atomic layer deposition method cycles are performed. The graph in FIG. 4B is PL spectra illustrating the visible photon energy range.

To be more specific, FIGS. 4C and 4D are data of photon energy absorption and light emission according to the number of atomic layer deposition method cycles of the Example. Values of the ZnO nanorods without RuO₂ coating were each plotted to be 1.

The graph in FIG. 4C illustrates a visible absorption ratio (at 1.6 eV photon energy). To be more specific, the visible absorption ratio of the ZnO nanorod coated with RuO₂ according to the Example and an organic substrate coated with RuO₂ was illustrated.

Further, from FIGS. 4A to 4D, it can be seen that 70 atomic nucleus deposition cycles are performed, the optical property of the RuO₂ particle itself is further largely appeared rather than the surface plasmon phenomenon due to the RuO₂ particle.

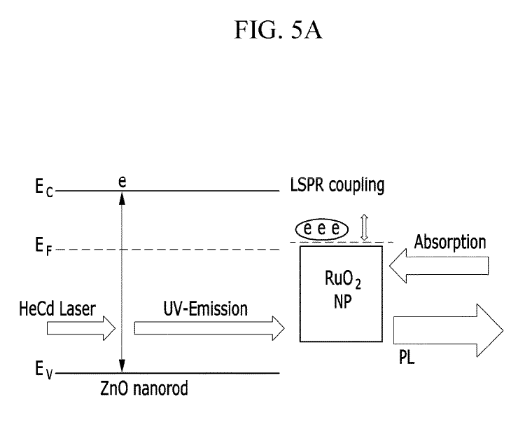

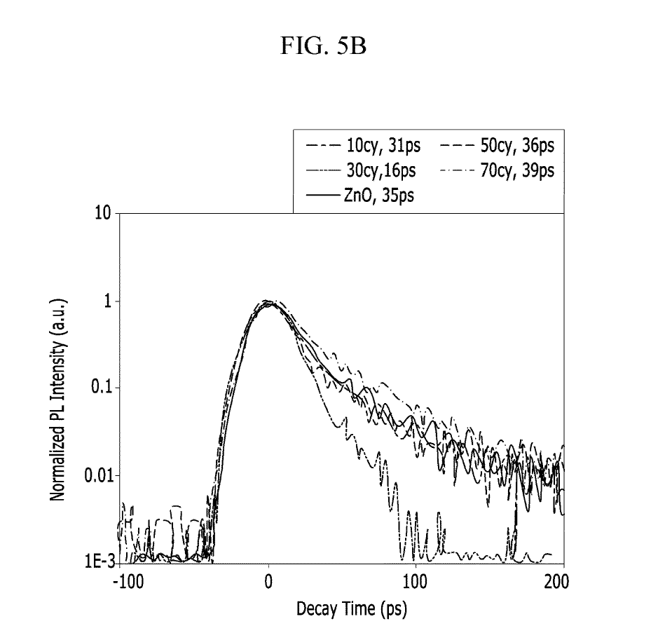

FIGS. 5A and 5B are a schematic theoretical explaining view of LSPR coupling for explanation an increase in absorption of visible rays and in UV light emission.

As described above, the LSPR is an abbreviation of the dual local surface plasmon resonance, and may increase visible absorption and UV light emission.

A theory of improvement of UV light emission of the LSPR may be described by FIG. 5A. To be more specific, the LSPR bandgap of the RuO₂ nanoparticle on the ZnO nanorod may be described from dynamic charge transfer from ZnO to RuO₂ and/or a size distribution of the RuO₂ nanoparticles. That is, hot carriers are produced from an interface of the ZnO and RuO₂ particles and the RuO₂ particles, the hot carriers exist in the nanostructure, and the hot carriers promote interfacial charge transfer, which finally increases a coupling of absorption and light emission. The LSPR coupling may be described by a Fermi's golden rule.

Further, as another aspect, the LSPR coupling may be described by a shortened PL decay curve. Previous study results reported with the measurement of time-resolved PL spectra revealed that the rate of enhanced spontaneous emission due to surface plasmon, a greater enhancement for the plasmon phenomenon of the nanowire or nanorod due to metal coating, and the like.

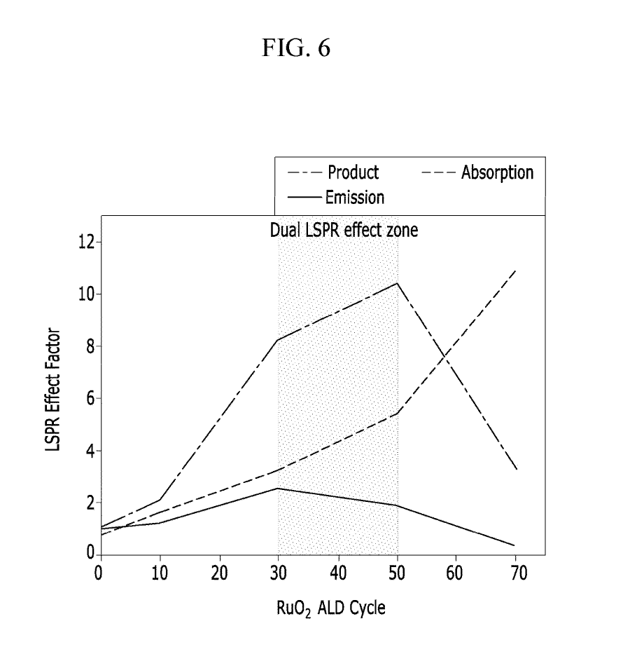

FIG. 6 is analysis data of factors of light absorption and light emission according to the number of the atomic layer deposition methods of the Examples. In FIG. 6, an effect factor 1 is a LSPR value of the ZnO nanorod without RuO₂ coating for each factor.

To be more specific, the data of FIG. 6 are extracted from the fitting of the PL decay curves by an inverse-filtering process with instrument response function (<15 ps).

As seen in FIG. 6, it can be seen that the maximum LSPR effect value is that of the Example according to 50 atomic layer deposition method cycles

Further, it can be seen that the Example of 70 cycles has a value that is lower than the LSPR effect value of the ZnO nanorod without the RuO₂ coating.

In conclusion, the aforementioned dual LSPR effect can be accomplished from the ZnO nanorod where the RuO₂ nanoparticles are applied on the surface thereof according to the exemplary embodiment of the present invention. To be more specific, the RuO₂ nanoparticles having the submetallic property may cause LSPR coupling due to an electric interfacial property with the ZnO nanorod.

Further, properties of electronic devices such as a LED and a solar cell may be improved from the ZnO nanorod where the RuO₂ nanoparticles of the present invention are applied on the surface.

Although the present invention has been described in connection with the exemplary embodiments of the present invention, it will be apparent to those skilled in the art that various modifications and changes may be made thereto without departing from the scope and spirit of the invention. Therefore, it should be understood that the above exemplary embodiments are not limitative, but illustrative in all aspects.

What is claimed is:

1. A nanorod comprising:
a ZnO nanorod; and
a coating layer disposed on a ZnO surface and including RuO₂ nanoparticles.

2. The nanorod of claim 1, wherein:
the RuO₂ nanoparticles have an average particle diameter of 20 nm or less.

3. The nanorod of claim 1, wherein:
the ZnO nanorod has a diameter of 20 nm or less.

4. The nanorod of claim 1, wherein:
the ZnO nanorod has a length of 300 nm or less.

5. The nanorod of claim 1, wherein:
the coating layer disposed on the ZnO surface and including the RuO₂ nanoparticles is an island type or a layered type.

6. A method of manufacturing a nanorod, comprising:
forming a ZnO nanorod on a substrate; and
forming a coating layer including RuO₂ nanoparticles on a surface of the ZnO nanorod formed on the substrate.

7. The method of manufacturing a nanorod of claim 6, wherein:
the forming of the coating layer including the RuO₂ nanoparticles on the surface of the ZnO nanorod formed on the substrate is performed by an atomic layer deposition method.

8. The method of manufacturing a nanorod of claim 7, wherein:
the atomic layer deposition method is performed in at least one or more cycles.

9. The method of manufacturing a nanorod of claim 8, wherein:
the atomic layer deposition method is performed one or more cycles and less than 70 cycles.

10. The method of manufacturing a nanorod of claim 8, wherein:
the atomic layer deposition method is performed 30 or more and 50 or less cycles.

11. The method of manufacturing a nanorod of claim 6, wherein:
the forming of the ZnO nanorod on the substrate is performed by a hydrothermal synthesis method.

12. The method of manufacturing a nanorod of claim 6, wherein:
the substrate is a silicon substrate, a plastic substrate, a glass substrate, a metal substrate, quartz, a metal oxide substrate, a metal nitride substrate, or a combination thereof.

13. The method of manufacturing a nanorod of claim 6, wherein:
the forming of the ZnO nanorod on the substrate includes:
forming a ZnO seed layer including a zinc precursor and HMT (hexamethylenetetramine) on the substrate; and
heating the substrate on which the ZnO seed layer is formed in a hydrothermal synthesis reactor to form the ZnO nanorod.

14. The method of manufacturing a nanorod of claim 13, wherein:
in the forming of the ZnO seed layer including the zinc precursor and HMT (hexamethylenetetramine) on the substrate, the zinc precursor is zinc nitrate, zinc sulfate, zinc chloride, zinc acetate, hydrate thereof, or a combination thereof.

15. The method of manufacturing a nanorod of claim 13, wherein:
in the heating of the substrate on which the ZnO seed layer is formed in the hydrothermal synthesis reactor to form the ZnO nanorod, the ZnO nanorod is formed under a condition of a temperature of 70 to 400° C. and a time of 30 minutes to 2 hours.

16. The method of manufacturing a nanorod of claim 6, wherein:
the forming of the coating layer including the RuO₂ nanoparticles on the surface of the ZnO nanorod formed on the substrate is performed by the atomic layer deposition method; and
the atomic layer deposition method is performed by using a ruthenium precursor, and argon-oxygen mixed gas as raw materials under a condition of a temperature of 100 to 400° C.

17. The method of manufacturing a nanorod of claim 16, wherein:
the ruthenium precursor is bis(ethylcyclopentadienyl)ruthenium (Ru(EtCp)₂).
